(19) United States
(12) Patent Application Publication
(10) Pub. No.: US 2021/0141710 A1
(43) Pub. Date: May 13, 2021

(54) DEVELOPMENT SUPPORT DEVICE

(71) Applicant: HITACHI AUTOMOTIVE SYSTEMS, LTD., Ibaraki (JP)

(72) Inventors: Yuichi KOMORIYA, Hitachinaka-shi (JP); Yuki HORITA, Tokyo (JP); Yasuhiro ODA, Hitachinaka-shi (JP); Fumio NARISAWA, Hitachinaka-shi (JP); Masato HAYASHI, Hitachinaka-shi (JP); Kohei SAKURAI, Hitachinaka-shi (JP); Takuya AZUMI, Suita-shi (JP); Syota TOKUNAGA, Suita-shi (JP)

(73) Assignee: HITACHI AUTOMOTIVE SYSTEMS, LTD., Ibaraki (JP)

(21) Appl. No.: 16/622,752

(22) PCT Filed: Jul. 18, 2018
(86) PCT No.: PCT/JP2018/026819

§ 371 Date: Dec. 13, 2019

(30) Foreign Application Priority Data
Jul. 25, 2017 (JP) 2017-143188

(51) Int. Cl. G06F 11/36; G06F 11/34; G06F 8/70

(52) U.S. Cl. CPC G06F 11/3608; G06F 8/70; G06F 11/3447

(57) ABSTRACT

The present invention makes efficient development possible by providing a development support device that automatically establishes a network model, messages to be transmitted and received, etc. for a cooperative simulation that connects a plurality of development support devices. The present invention is characterized in that: a development support device generates a communication definition file in a format that can be read and executed by a development support device; and development support device reads the communication definition file and thereby automatically establishes messages to be transmitted and received by development support device.

### TECHNICAL FIELD

The present invention relates to processing for enabling different development support devices to operate in cooperation.

### BACKGROUND ART

In advanced development support or advanced development of automated driving, mainstream development is development using MATLAB/Simulink (MATLAB (registered trademark), Simulink (registered trademark)) for development of control algorithms and signal processing or using Robot Operating System (ROS), which is an open software providing libraries or tools for supporting development in the robot development field.

Now there is a demand for connecting these different development support devices via a network to be able to perform simulation.

This would enable the advantages and features of each of development support devices to be incorporated individually, facilitating implementation of simulation using mixed technologies in cooperation.

PTL 1 describes an information processing device and a method for using a plurality of simulators in cooperation. The disclosed device and method are a device and a method in which a scenario execution unit gives each of simulators an execution instruction of an operation scenario having time information necessary for the simulator so as to allow each of the simulators to work in synchronization.

PTL 2 describes a simulation device having a cooperative simulation environment including a system simulator and a CPU simulator using a microcomputer, in which time-stamped data is exchanged between both of the simulators and the CPU simulator generates an interrupt in accordance with the time-stamped data to perform synchronization.

### CITATION LIST

### Patent Literature

PTL 1: JP 2014-29639 A

PTL 2: JP 2013-84163 A

### SUMMARY OF INVENTION

### Technical Problem

In the technique of PTL 1, an external input is used to generate a scenario and the scenario is executed to allow the simulators to work in cooperation. At this time, the input and output required by each of the simulators need to be set in advance.

In the technique of PTL 2, the CPU simulator synchronizes one of the simulators and emphasizes it in accordance with a synchronization signal. Similarly to PTL 1, the input and output required by each of the simulators need to be set in advance.

In a cooperative simulation, as described above, connecting a plurality of development support devices capable of performing different simulation verifications, there occurs a Problem of connection of these devices in a case where there is a difference in the simulation model or network model between one development support device and the other development support device. In a case where one development support device uses the time period as the activation factor, and the other development support device uses the transmission/reception event with the communication partner as the activation factor, there is a need to set communication models and transmission/reception processing with the connection destination so as to match each of the development support devices.

For this purpose, there has been a need to set a message to be transmitted or received on one development support device and manually perform setting on the other development support device, adapted to match the network model and the specifications of the message to be transmitted or received of the one development support device, which has been a problem of increased development man-hours.

### Solution to Problem

In order to solve the above-described problem, there is provided a technology, in cooperative simulation of development support devices in which network models of the communication partner or messages to be transmitted or received are different, in which a communication definition file executable by one development support device is generated by the other development support device, and the one development support device reads a communication definition file to automatically establish a message to be transmitted or received by the other development support device.

### ADVANTAGEOUS EFFECTS OF INVENTION

With the configuration in which one development support device generates a communication definition file and the other development support device reads the communication definition file in a cooperative simulation between development support devices in which network models and messages to be transmitted or received are different, it is possible to automatically construct a network and establish a message to be transmitted or received, enabling activation of the other development support device at the timing of the one development support device. The configuration described above eliminates a need to perform installation processing on the other development support device, leading to enhancement of the development efficiency.

### BRIEF DESCRIPTION OF DRAWINGS

FIG. 1 is a configuration diagram of a cooperative system of development support devices.

FIG. 2 is an example of a communication definition file.

FIG. 3 is a flowchart from the activation of a development support device 1 and a development support device 2 to the start of simulation.

FIG. 4 is a flowchart illustrating processing of the development support device 1.

FIG. 5 is a flowchart illustrating processing of the development support device 2.

FIG. 6 is a schematic diagram of an example of a cooperative simulation in which a plurality of development support devices is connected.

FIG. 7 is a diagram illustrating configurations of Simulink1, ROS1, and ROS3.

FIG. 8 is an example of a communication definition file.

FIG. 9 is an example of a communication definition file.

### DESCRIPTION OF EMBODIMENTS

Embodiments of the present invention will be described below with reference to the accompanying drawings.

### First Embodiment

A mechanism for constructing a network environment and activating and terminating a system as a cooperation partner in a cooperative simulation environment using MATLAB/Simulink (MATLAB (registered trademark), Simulink (registered trademark)) and Robot Operating System (ROS) according to a first embodiment will be described with reference to the drawings.

FIG. 1 is a configuration diagram of a cooperative system for development support devices according to the first embodiment. A development support device 1 is an example of using a simulator having a fixed time period as an activation factor, and is provided as a personal computer including: a simulation model 6 that operates at a predetermined sampling period and that is used for model-based development in vehicle control and signal control development, stored in a model storage device 7; and an external data transmission/reception device 9.

Examples of the external data transmission/reception device 9 include Robotics System Toolbox that can construct a network model of the Robot Operating System (ROS) provided by MATLAB/Simulink (MATLAB (registered trademark), Simulink (registered trademark)). The development support device 1 further includes an external setting file read execution device 3 and a synchronization device 8.

The development support device 2 is an example of using a simulator that uses a communication event as an activation factor, and includes a distributed system in which a plurality of pieces of software having individual functions is executed simultaneously as nodes with the nodes exchanging data with each other. This device is provided as a personal computer having a publish-subscribe network model, including the simulator 15 installed to be executed by a simulator execution unit 16, and further equipped with an external data transmission/reception device 17.

Examples of this include Robot Operating System (ROS), which is a software framework for robots as open source software that provides a variety of libraries and drivers for robot development. In the present embodiment, the simulator 15 includes a calculation function group developed by a developer and a library group provided by ROS in addition to the simulator to be verified. The development support device 2 further includes a communication definition generation device 10 and a development support device management device 12.

Although FIG. 1 illustrates a configuration including two development support devices, the number of devices is not limited, and the number of devices may be greater than illustrated in the present embodiment. In the present embodiment, description will be made assuming that the development support device 1 is MATLAB/Simulink (MATLAB (registered trademark), Simulink (registered trademark)), and the development support device 2 is ROS.

The communication definition generation device 10 is a device that preliminarily generates a communication definition file 11 before simulation verification. The communication definition file 11 is a file generated in a scripting language that is a simple program language. Here, although the file is defined as a scripting language, there is no limitation in the language or file. In the present embodiment, it is assumed that MATLAB/Simulink (MATLAB (registered trademark), Simulink (registered trademark)) includes a MATLAB source code that can be read and executed.

FIG. 2 is an example of the communication definition file 11 generated by the communication definition generation device 10. In FIG. 2, the second line indicates the definition of the node type of the development support device 1. The fourth line indicates the definition for enabling reception on the development support device 1 from the outside. The definition includes definitions of the message name and message data type. The sixth line indicates the definition for enabling transmission on the development support device 1 to the outside. The definition includes definitions of the name and data type of a message to be transmitted. The eighth line indicates the definition of the transmission period of the message to be transmitted. In the example of FIG. 2, the period is defined as 10 [Hz]. The transmission period may be defined as time or the like other than the frequency.

The communication definition reading unit 5 reads and executes the communication definition file 11, whereby the development support device 1 automatically reads and executes the defined nodes, messages to be received, and messages to be transmitted so as to allow the messages to be automatically established. The embodiment is not limited to the programs. Alternatively, a graphical user interface and other methods may be used.

In communicating between the development support device and the development support device 2, it is necessary to manually install messages to be transmitted and received between the development support devices, which increases the development man-hours. However, generating the communication definition file on the development support device 2 would eliminate necessity of performing installation on the development support device 1, leading to the reduction of the development man-hours. Furthermore, the development support device 1 automatically reads the definition file, leading to enhancement of the development efficiency.

The development support device management device 12 includes an external development support device management unit 13 and a development support device activation unit 14. The development support device management device 12 mainly manages the system and is formed by a program or a graphical user interface (GUI).

The development support device activation unit 14 manages the simulator 15 and the external development support device management unit 13.

The external development support device management unit 13 is a device that instructs the cooperation target development support device to perform activation and execution. In response to an activation instruction from the external development support device management unit 13, the development support device execution unit 4 activates the development support device 1 and the simulation model 6 in response to the request.

FIG. 3 is a flowchart of processing from the activation to the start of simulation, performed by the development support device 1 and the development support device 2. First, the development support device management device 12 is activated (S101). Next, after execution of the development support device activation unit 14 (S102) and activation of the simulator 15 of the development support device 2 (S103), the external development support device management unit 13 is executed (S104). After execution of the external development support device management unit 13, the development support device execution unit 4 of the development support device 1 is executed (S106), and then, the communication definition file is read by the communication definition reading unit 5 (S107). The data to be received by the development support device 1 via the external data transmission/reception device 9, the data to be transmitted, and the transmission/reception period are automatically established. Finally, the simulation model 6 is activated (S108), and the cooperative simulation is started while transmission and reception of information is performed between both sides. The above-described configuration eliminates the necessity for the developer to individually activate each of the development support devices, leading to enhancement of the operability.

The synchronization device 8 is a device that adds time information to a message transmitted or received from the development support device 2 and transmits or receives information in accordance with the execution period of the development support device 1. For example, a message transmitted by the development support device 2 and received by the development support device 1 might have an indefinite delay due to the fact that the message is a result of calculation performed 1 [s] before, for example. For this reason, it is possible to enhance the reliability of the simulation result by performing control to minimize the time difference in simulation performed by the development support device 1 and the development support device 2.

FIG. 4 illustrates a flowchart from the start to the end of the simulation of the development support device 1. As illustrated in FIG. 4, the development support device execution unit 4 receives an activation instruction for the development support device 1, and transmits an activation instruction to the simulation model 6 (S110). After receiving the activation instruction, the simulation model 6 activates the simulation model (S111). After the simulation model 6 is activated, the communication setting of the external data transmission/reception device 9 is automatically performed (S112), and the reception processing is started (S113).

After the activation processing of the development support device 1, the simulation model 6 is executed in accordance with the sampling period (S114), and the simulation model processing results or the like are stored in the model storage device (S115). Information to be transmitted by the simulation model 6 is stored in the synchronization device 8 (S116). Time information is added (S117) to the information to be transmitted that has been stored in the synchronization device 8, and then, the information to be transmitted is transmitted to the development support device 2 in accordance with the transmission period set in the communication definition file (S118). The above processing is repeated until an end signal from the development support device 2 is received.

FIG. 5 is a flowchart from the start to the end of the simulation on the development support device 2. The developer activates the development support device management device 12 (S120) and executes the development support device activation unit 14 (S121). Next, the external development support device management unit 13 is executed, an activation instruction is transmitted to the development support device 1 (S122), and then the simulator 15 is activated (S123).

After the activation processing in the development support device 2 as described above, the external data transmission/reception device 17 receives information and transmits the received information to the simulator execution unit (S124). The simulator execution unit 16 gives an execution instruction to the simulator 15 from the received information (S125). The simulator 15 executes processing in accordance with the execution instruction from the simulator execution unit 16 (S126), and transmits the execution result of the simulator to the outside (S127). The above processing is repeated until the simulator 15 is finished. When the simulator 15 is finished (S128), an end signal is transmitted to the development support device 1 (S129), so as to finish the cooperative simulator.

According to the first embodiment, one development support device creates a communication definition file that defines a communication model of the other development support device, and the other development support device automatically incorporates the communication definition file, enabling easy construction of an environment for mutual communication. Moreover, in the case of a development support device that performs reception from a publish-subscribe communication model such as ROS, input/output is performed in synchronization with the control period between the development support devices by the synchronization device 8, making it possible to implement a highly accurate cooperative simulation.

### Second Embodiment

A second embodiment will describe an example of communication definition for achieving cooperative simulation in a cooperative simulation in which a plurality of development support devices is connected.

FIG. 6 is a schematic diagram in which a plurality of development support devices such as MATLAB/Simulink (MATLAB (registered trademark), Simulink (registered trademark)) and ROS are connected via a network. For example, Simulink1 represents a vehicle simulator referred to as a plant model that simulates the engine, braking, steering, etc. mounted on the vehicle. Simulink2 represents a simulation for integrated control in which how the vehicle is going to travel is judged and controlled from the surrounding environment and the state of the vehicle. ROS1 represents a simulation that simulates an automobile traveling environment. ROS2 represents a simulation that performs integrated recognition of information from sensors attached to the vehicle. ROS3 represents a simulation for estimating the position of an own vehicle from sensors and maps. These devices are interconnected via a TCP/UDP network (network 19 connecting each of the development support devices). Here, each of Simulink1 and Simulink2 is assumed to have a configuration similar to the configuration of the development support device 1 in the first embodiment. Each of ROS1, ROS2, and ROS3 is assumed to have a configuration similar to the configuration of the development support device 2 in the first embodiment. In the embodiment, the connection method is not limited to the TCP/UDP network, and other methods may be used.

Based on the above configuration, the following will describe generation of a communication definition file in a case, for example, where the development support devices that cooperate with Simulink1 are ROS1 and ROS3, and where the development support device that cooperates with Simulink2 is ROS2.

Since the cooperative simulation of Simulink 2 and ROS2 is similar to the case of the first embodiment, detailed description will be omitted. In a case where each of ROS1 and ROS3 cooperates with the same Simulink1, ROS1 and ROS3 individually generate communication definition files.

FIG. 7 illustrates configurations of Simulink1, ROS1, and ROS3. Simulink 1 includes an external setting file read execution device 21, ROS1 includes a communication definition generation device 23, and ROS2 includes a communication definition generation device 25. Simulink1 has a configuration similar to the configuration of the development support device 1 in FIG. 1, and each of ROS1 and ROS3 has a configuration similar to the configuration of the development support device 2 in FIG. 1, although the components are omitted in FIG. 7. For achieving cooperative simulation, ROS1 generates a communication definition file a(24) from the communication definition generation device 23, and ROS3 generates a communication definition file b(26) from the communication definition generation device 25 for preparation. Simulink1 can automatically perform communication settings with two development support devices by reading the communication definition file a(24) and communication definition file b(26) from the communication definition reading unit 22 at the time of activation. FIGS. 8 and 9 illustrate examples of the communication definition file 11. FIG. 8 illustrates a communication definition file generated by ROS1 and FIG. 9 illustrates a communication definition file generated by ROS3.

Since the processing content of each of lines has been described in FIG. 2, description will be omitted. In FIGS. 8 and 9, a node name, a message to be transmitted and received, and a transmission period are defined. Note that defining a node name using a same name or defining transmission and reception messages using a same name might cause an error in Simulink1 or in the network, and thus, different names are used in definition. In addition, when the messages to be transmitted to Simulink1 are the same in ROS1 and ROS3, generating the message by one development support device alone would enable communication.

The above embodiments would not limit a combination, and individual embodiments may be combined.

In the case of the above-described cooperative simulation environment including the plurality of development support devices with different functions, each of ROS1, ROS2, and ROS3 flexibly defines, in the communication definition file, information to be transmitted to or received from Simulink1 or Simulink2, and then, the corresponding MATLAB/Simulink (MATLAB (registered trademark), Simulink (registered trademark)) performs automatic setting for this, enabling communication to be easily established, leading to implementation of a plurality of cooperative simulations. In addition, parallel distributed processing that requires a lot of man-hours for installation can be easily implemented by a device that can generate and read communication definition files, enabling the developer to perform parallel development and reduce the development man-hours.

The present invention is not limited to the above-described embodiments, but may include various types of modification. For example, the above-described embodiments give detailed explanation just to allow the present invention to be clearly understood. Therefore, the present invention is not limited to the case having all of components in the configuration. In addition, a portion of configuration of an embodiment can be replaced with a portion of configuration of another embodiment. A portion or the configuration of another embodiment can be added to a certain embodiment. Moreover, regarding the portions of the configuration of each of the embodiments, addition, deletion, and replacement from another configuration would be possible. Moreover, the above configurations, functions, processing devices, or the like, may be implemented by hardware by designing a portion or all with an integrated circuit, for example. Moreover, each of the above-described configurations, functions, or the like, may be implemented with software by a processor by interpreting and executing a program designed to implement individual functions. Information such as programs, tables, files used to implement each of functions can also be located in a recording device such as memory, a hard disk, a solid state drive (SSD), or a recording medium such as an IC card, SD card, and DVD.

### REFERENCE SIGNS LIST

1 development support device

2 development support device

3 external setting file read execution device

4 development support device execution unit

5 communication definition reading unit

6 simulation model

7 model storage device

8 synchronization device

9 external data transmission/reception device

10 communication definition generation device

11 communication definition file

12 development support device management device

13 external development support device management unit

14 development support device activation unit

15 simulator

16 simulator execution unit

17 external data transmission/reception device

19 network connecting each of development support devices

21 external setting file read execution device

22 communication definition reading unit

23 communication definition generation device

24 communication definition file a

25 communication definition generation device

26 communication definition file b

1. A development support device comprising different types of verification devices,
wherein one of the verification devices, namely, one verification device, includes a generation unit that generates model setting data that can be read by the other verification device, and
the one verification device instructs the other verification device on an activation timing in a case where the one verification device has generated the model setting data.

2. The development support device according to claim 1,
wherein the other verification device includes a reading unit that reads the model setting data transmitted from the one verification device.

3. The development support device according to claim 1,
wherein, in a case where the one verification device and the other verification device are connected to each other, the other verification device activates a model based on the model setting data.

4. The development support device according to claim 1,
wherein, in a case in claim 1 where the one verification device completes the verification, the one verification device notifies the other verification device of the completion.

5. The development support device according to claim 4,
wherein, the other verification device finishes the verification on the basis of a completion notification from the one verification device.

6. The development support device according to claim 1, further comprising a synchronization device having time information for achieving synchronization between the one verification device and the other verification device.

7. The development support device according to claim 1,
wherein the model setting data includes a defined node, a message to be received, a message to be transmitted, and time information.
